(19) United States
(12) Patent Application Publication
(10) Pub. No.: US 2019/0096879 A1
(43) Pub. Date: Mar. 28, 2019

(54) SEMICONDUCTOR DEVICE AND METHOD OF MANUFACTURING THE SAME

(71) Applicant: Nuvoton Technology Corporation, Hsinchu (TW)

(72) Inventors: Chih-Wei Chen, Hsinchu (TW); Heng-Kuang Lin, Hsinchu (TW)

(73) Assignee: Nuvoton Technology Corporation, Hsinchu (TW)

(21) Appl. No.: 16/137,524

(22) Filed: Sep. 20, 2018

(30) Foreign Application Priority Data
Sep. 22, 2017 (TW) 106132526

(51) Int. Cl. H01L 27/07; H01L 29/10; H01L 29/417; H01L 29/778; H01L 29/66; H01L 21/02; H01L 21/265; H01L 21/266; H01L 29/20; H01L 21/324; H01L 29/861; H01L 29/868; H01L 29/205

(52) U.S. Cl. CPC H01L 27/0727; H01L 29/1033; H01L 29/4175; H01L 29/7787; H01L 29/66462; H01L 21/0254; H01L 29/66204; H01L 21/266; H01L 29/2003; H01L 21/3245; H01L 29/861; H01L 29/868; H01L 29/205; H01L 21/26546

(57) ABSTRACT

Provided is a semiconductor device including a substrate, a diode, a channel layer, a barrier layer, a first dielectric layer, a source, a drain, and a gate. The diode is disposed over the substrate or in the substrate. The channel layer is disposed over the diode. The barrier layer is disposed over the channel layer. The first dielectric layer is disposed over the barrier layer. The source is electrically connected to a first region of the diode by a first conductive via through the first dielectric layer, the barrier layer, and the channel layer. The drain is electrically connected to a second region of the diode by a second conductive via through the first dielectric layer, the barrier layer, and the channel layer. The gate is disposed over the channel layer between the source and the drain.

### CROSS-REFERENCE TO RELATED APPLICATION

This application claims the priority benefit of Taiwan application no. 106132526, filed on Sep. 22, 2017. The entirety of the above-mentioned patent application is hereby incorporated by reference herein and made a part of this specification.

### BACKGROUND

### Field of the Invention

The invention relates to an integrated circuit and a method of manufacturing the same. More particularly, the invention relates a semiconductor device and a method of manufacturing the same.

### Description of Related Art

In recent years, III-V group compound semiconductor-based high electron mobility transistor (HEMT) devices, as having a high breakdown voltage, a larger bandgap and excellent carrier mobility, can exhibit preferable low impedance conductance through a two-dimensional electron gas (2DEG) generated by polarization, such that a III-V group compound semiconductor material may be widely applied in high-frequency devices and power devices. A metal-insulator-semiconductor HEMT (MIS-HEMT) device is one kind of the HEMT devices. The MIS-HEMT device has a gate dielectric layer capable of reinforcing device performance at an interface between a metal and a semiconductor, such as a high breakdown voltage, a low gate leakage current, a low device impedance and a wide gate operation range.

However, the structure of the gate dielectric layer may easily cause additional interface trapping and so causes issues, such as pinch-off voltage shift, current collapse, reliability failure and so on, which may affect electricity of the MIS-HEMT device. The above-mentioned electricity issues incur limitations to the application of the MIS-HEMT device. Thus, how to prevent the MIS-HEMT device from generating the interface trapping has been an important subject.

### SUMMARY

The invention provides a semiconductor device capable of connecting a metal-insulator-semiconductor high electron mobility transistor (MIS-HEMT) device with a diode in parallel to prevent interface trapping, so as to enhance device performance.

The invention provides a method of manufacturing a semiconductor device which is capable of integrating an MIS-HEMT device and a diode in one chip by using a single-chip integration technique to significantly reduce a use area of the chip, so as to meet requirements for miniaturization of electronic devices.

According to an embodiment of the invention, a semiconductor device including a substrate, a diode, a channel layer, a barrier layer, a first dielectric layer, a source, a drain, a gate, and a two-dimensional electron gas (2DEG) is provided. The diode is disposed over a substrate or in the substrate. The diode includes a first region with a first conductive type and a second region with a second conductive type, and the first conductive type is different from the second conductive type. The channel layer is disposed over the diode. The barrier layer is disposed over the channel layer. The first dielectric layer is disposed over the barrier layer. The source is electrically connected to the first region of the diode by a first conductive via through the first dielectric layer, the barrier layer, and the channel layer. The drain is electrically connected to the second region of the diode by a second conductive via through the first dielectric layer, the barrier layer, and the channel layer. The gate is disposed over the channel layer between the source and the drain. The 2DEG is disposed in the channel layer between the source and the drain.

According to an embodiment of the invention, a semiconductor device including a substrate, a channel layer, a barrier layer, a dielectric layer, a source, a drain, a gate, an anode, a cathode, and a two-dimensional electron gas (2DEG). The channel layer is disposed over a substrate. The barrier layer is disposed over the channel layer. The dielectric layer is disposed over the barrier layer. The source passes through the dielectric layer and the barrier layer and is electrically connected with the channel layer. The drain passes through the dielectric layer and the barrier layer and is electrically connected with the channel layer. The gate is disposed over the dielectric layer between the source and the drain. The anode passes through the dielectric layer and is electrically connected with the barrier layer and electrically connected with the source by a first interconnect. The anode and the barrier layer form a Schottky diode. The cathode passes through the dielectric layer and the barrier layer and is electrically connected with the channel layer and electrically connected with the drain by a second interconnect. The 2DEG is disposed in the channel layer between the source and the drain and disposed in the channel layer between the source and the cathode.

According to an embodiment of the invention a method of manufacturing a semiconductor device is provided, which includes the following steps. A channel layer, a barrier layer and a dielectric layer is sequentially formed over a front surface of a substrate. A first region with a first conductive type and a second region with a second conductive type are respectively formed in the substrate, wherein the first conductive type is different from the second conductive type. A first conductive via is formed in the dielectric layer, the barrier layer and the channel layer, such that a source is electrically connected with the first region by the first conductive via. A second conductive via is formed in the dielectric layer, the barrier layer and the channel layer, such that a drain is electrically connected with the second region by the second conductive via. A gate is formed on the dielectric layer between the source and the drain. A two-dimensional electron gas (2DEG) is formed in the channel layer between the source and the drain.

Based on the above, in the invention, the MIS-HEMT device and the diode can be connected in parallel and integrated with each other on the same chip by utilizing the single-chip integration technique, which can not only significantly reduce the use area of the chip, but also prevent the interface trapping, so as to enhance the device performance.

In order to make the aforementioned and other features and advantages of the invention more comprehensible, several embodiments accompanied with figures are described in detail below.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1A to FIG. 1E are schematic cross-sectional views showing a manufacturing process of a semiconductor device according to a first embodiment of the invention.

FIG. 2 is a schematic cross-sectional view showing a semiconductor device according to a second embodiment of the invention.

FIG. 3 is a schematic cross-sectional view showing a semiconductor device according to a third embodiment of the invention.

FIG. 4 is a schematic cross-sectional view showing a semiconductor device according to a fourth embodiment of the invention.

FIG. 5 is a schematic cross-sectional view showing a semiconductor device according to a fifth embodiment of the invention.

FIG. 6 is a schematic cross-sectional view showing a semiconductor device according to a sixth embodiment of the invention.

FIG. 7 is a schematic cross-sectional view showing a semiconductor device according to a seventh embodiment of the invention.

### DESCRIPTION OF EMBODIMENTS

The invention is illustrated more comprehensively with reference to the following drawings which show embodiments of the present invention. However, the invention can further be implemented in various manners and should not be limited to the embodiments set forth hereinafter. Thicknesses of layer and areas in the drawings are exaggerated for the sake of clarity. The same or similar referral numerals are used to represent the same or the like parts and thus, will not be repeatedly described.

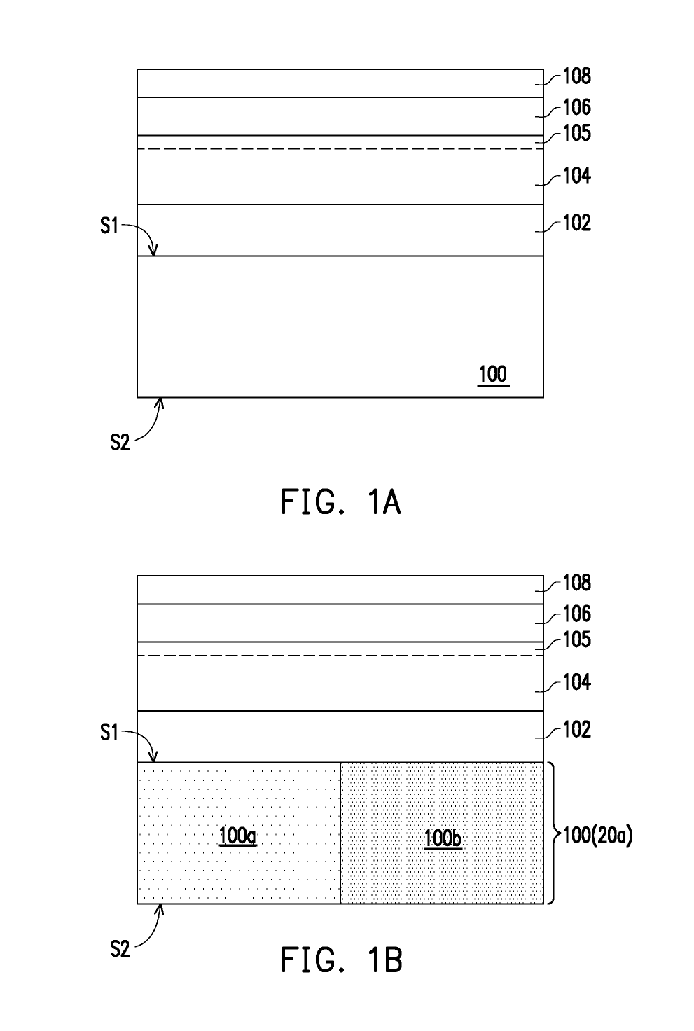

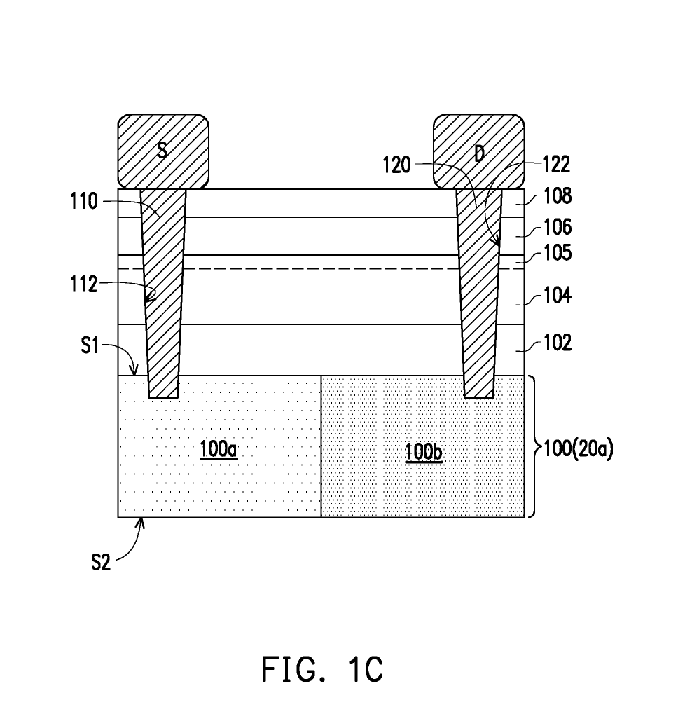

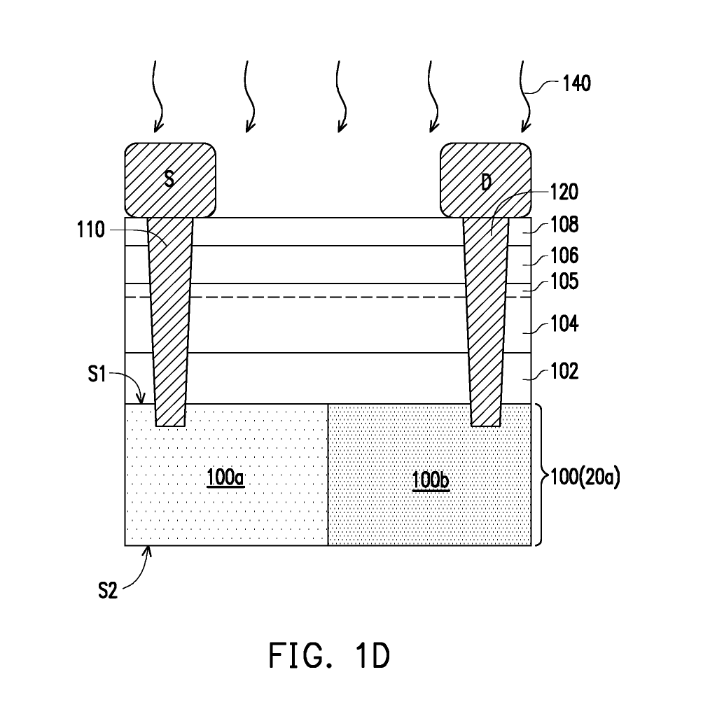

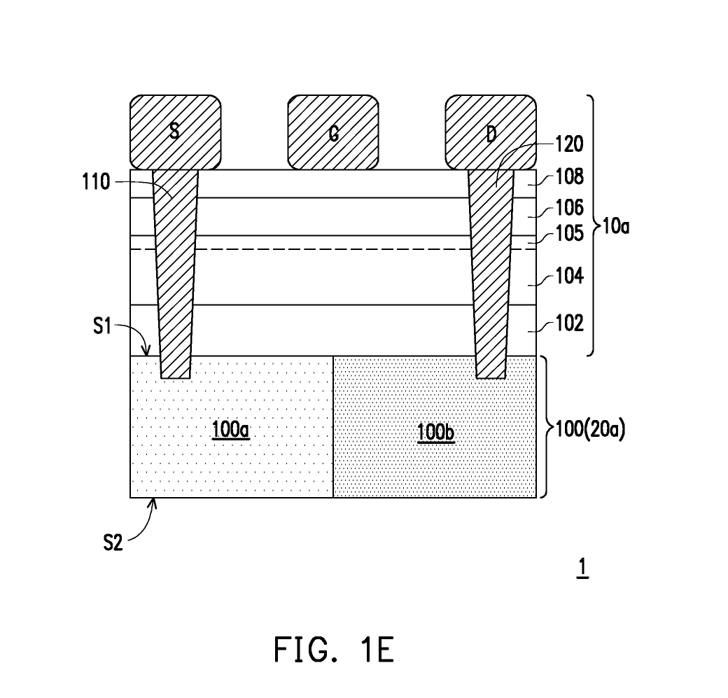

Referring to FIG. 1A, a first embodiment of the invention provides a method of manufacturing a semiconductor device, which includes the following steps. First, a substrate 100 is provided. The substrate 100 has a front surface S1 and a back surface S2 which are opposite to each other. In an embodiment, the substrate 100 may be considered as a growth substrate which is made of, for example, sapphire, SiC, AlN, Si, Ge, GaAs, InP, GaP, GaN or a combination thereof. In the present embodiment, the substrate 100 may be a Si substrate.

Then, a buffer layer 102, a channel layer 104, a barrier layer 106 and a dielectric layer 108 are sequentially formed on the front surface S1 of the substrate 100. In an embodiment, a method of forming the buffer layer 102, the channel layer 104, the barrier layer 106 and the dielectric layer 108 may be an epitaxial growth method, such as a metal-organic chemical vapor deposition (MOCVD) method or a molecular beam epitaxy (MBE) method.

Specifically, the buffer layer 102 may be disposed between the substrate 100 and the channel layer 104 to reduce a difference of lattice constant and a difference of coefficients of thermal expansion (CTE) between the substrate 100 and the channel layer 104. In an embodiment, a material of the buffer layer 102 includes a III group nitride, e.g., a III-V group compound semiconductor material, and the buffer layer 102 may have a single-layer structure or a multi-layer structure. In an alternative embodiment, the material of the buffer layer 102 includes AlN, GaN, AlGaN, InGaN, AlInN, AlGaInN or a combination thereof.

The channel layer 104 may be disposed between the buffer layer 102 and the barrier layer 106. In the presence of a heterojunction formed between the channel layer 104 and the barrier layer 106, a two-dimensional electron gas (2DEG) 105 with a high electron mobility is formed in a region of the channel layer 104 which is adjacent to the barrier layer 106. In an embodiment, a material of the channel layer 104 includes a III group nitride, e.g., a III-V group compound semiconductor material, which may be undoped or unintentionally doped GaN, for example. However, the invention is not limited thereto, and in other embodiments, as long as a bandgap of a material of the channel layer 104 is different from a bandgap of a material the barrier layer 106, the material of the channel layer 104 falls within the scope of the invention.

The barrier layer 106 may be disposed between channel layer 104 (or the 2DEG 105) and the dielectric layer 108. In an embodiment, a material of the barrier layer 106 includes a III group nitride, e.g., a III-V group compound semiconductor material, and the barrier layer 106 may have a single-layer or a multi-layer structure. In an embodiment, the barrier layer 106 includes AlGaN, AlInN, AlN, AlGaInN or a combination thereof. In an embodiment, the barrier layer 106 may also be a doped or undoped layer.

The dielectric layer 108 may be disposed on the barrier layer 106. In an embodiment, a material of the dielectric layer 108 includes a dielectric material, and the dielectric layer 108 may have a single-layer structure or a multi-layer structure. In an embodiment, the material of the dielectric layer 108 includes Al₂O₃, SiN, SiO, AlN or a combination thereof.

Referring to FIG. 1B, a first region 100a with a first conductive type and a second region 100b with a second conductive type are respectively formed in the substrate 100. In an embodiment, the first conductive type and the second conductive type are different. When the first conductive type is an N-type, the second conductive type is a P-type, or when the first conductive type is a P-type, the second conductive type is an N-type. A dopant of the P-type is, for example, boron, and a dopant of the N-type is, for example, phosphorous or arsenic. In the present embodiment, the first conductive type being the P-type, and the second conductive type being the N-type is taken as an example for description, but the invention is not limited thereto.

Specifically, the step of respectively forming the first region 100a and the second region 100b in the substrate 100 will be set forth as follows. With the back surface S2 of the substrate 100 facing upwards, a first mask pattern (which is not shown) is formed on the back surface S2 of the substrate 100 to cover the second region 100b and expose the first region 100a. A first ion implantation process is performed on the first region 100a, such that a conductive type of the substrate 100 in the first region 100a is changed to the P-type. In an embodiment, a dopant implanted into the first region 100a may be, for example, boron, and a doping concentration thereof may be, for example, 1×10¹⁸/cm³ to 1×10²° /cm³.

After the first mask pattern is removed, a second mask pattern (which is not shown) is formed on the back surface S2 of the substrate 100 to cover the first region 100a and expose the second region 100b. A second ion implantation process is performed on the second region 100b, such that a conductive type of the substrate 100 in the second region 100b is changed to the N-type. In an embodiment, a dopant implanted into the second region 100b may be, for example, phosphorous or arsenic, and a doping concentration thereof may be, for example, 1×10¹⁸/cm³ to 1×10²⁰/cm³.

In the present embodiment, the first region 100a is formed before the second region 100b is formed, but the invention is not limited thereto. In other embodiments, the second region 100b may be formed before the first region 100a is formed. In an alternative embodiment, a lithography and ion implantation process may be performed by using a P-type substrate to form an N-type doped region in the P-type substrate.

It should be noted that as shown in FIG. 1B, the first region 100a and the second region 100b are connected with each other and form the entire substrate 100. In the present embodiment, the first region 100a with the P-type and the second region 100b with the N-type may form a P-N junction diode 20a. The P-N junction diode 20a is embedded in the substrate 100. In other words, the entire substrate 100 becomes the P-N junction diode 20a. In some embodiments, as shown in FIG. 1B, an orthographic projection of the 2DEG 105 over the front surface (top surface) S1 of the substrate 100 is overlapped to the diode 20a.

Referring to FIG. 1C, after the second mask pattern is removed, the front surface S1 of the substrate 100 is changed to face upwards. Thereafter, a first conductive via 110 and a second conductive via 120 are formed in the dielectric layer 108, the barrier layer 106, the channel layer 104 and the buffer layer 102. A source S may be electrically connected with the first region 100a in the substrate 100 by the first conductive via 110. A drain D may be electrically connected with the second region 100b in the substrate 100 by the second conductive via 120.

To be specific, a step of forming the first conductive via 110 and the second conductive via 120 may include forming a third mask pattern (which is not shown) on the dielectric layer 108 to define positions of the first conductive via 110 and the second conductive via 120. Then, by using the third mask pattern as an etching mask, a part of the dielectric layer 108, a part of the barrier layer 106, a part of the channel layer 104 and a part of the buffer layer 102 are removed, so as to form a first opening 112 and a second opening 122. The first opening 112 exposes a part of the surface of the first region 100a of the substrate 100, and the second opening 122 exposes a part of the surface of the second region 100b of the substrate 100. Thereafter, the conductive material is filled in the first opening 112 and the second opening 122 by an electroplating method or a vapor deposition method to form the first conductive via 110 in the first opening 112, form the source S on the first conductive via 110, form the second conductive via 120 in the second opening 122 and form the drain D on the second conductive via 120. In an embodiment, the conductive material may include a metal (e.g., Ta, Ti, W, Pd, Ni, Au, Al or a combination thereof), a metal nitride (e.g., TaN, TiN, WN or a combination thereof), a metal silicide (e.g., WSiₓ) or a combination thereof.

Referring to FIG. 1D, after the third mask pattern is removed, an annealing process 140 is performed. In the present embodiment, the annealing process 140 may not only repair lattice damages of the first region 100a and the second region 100b after the ions are implanted, but also diffuse the metal (e.g., Al) in the first conductive via 110 and the second conductive via 120 into a semiconductor layer (e.g., the first region 100a, the second region 100b and the channel layer 104) to form an ohmic contact. In an embodiment, the annealing process 140 includes a rapid thermal annealing (RTA) process or a furnace annealing process. Taking the RTA process for example, a treatment temperature of the RTA process may be, for example, 800° C. to 1000° C., and a processing time thereof may be, for example, 10 to 120 seconds.

Referring to FIG. 1E, a gate G is formed on the dielectric layer 108 between the source S and the drain D. In an embodiment, a material of the gate G includes a conductive material. The conductive material may include a metal (e.g., Ta, Ti, W, Pd, Ni, Au, Al or a combination thereof), a metal nitride (e.g., TaN, TiN, WN or a combination thereof), a metal silicide (e.g., WSiₓ) or a combination thereof. In an embodiment, the source S, the drain D and the gate G may be made of the same material, but the invention is not limited thereto. In other embodiments, the source S, the drain D and the gate G may be made of different materials.

Referring to FIG. 1E, the first embodiment provides a semiconductor device 1 including the substrate 100, the buffer layer 102, the channel layer 104, the barrier layer 106, the dielectric layer 108, the source S, the drain D and the gate G. The buffer layer 102, the channel layer 104 (which has the 2DEG 105 in the region adjacent to the barrier layer 106), the barrier layer 106 and the dielectric layer 108 are sequentially disposed on the front surface SI of the substrate 100. The substrate 100 includes the first region 100a and the second region 100b which are connected with each other and form the P-N junction diode 20a. The source S is electrically connected with the first region 100a by the first conductive via 110 passing through the dielectric layer 108, the barrier layer 106, the channel layer 104 and the buffer layer 102. The drain D is electrically connected with the second region 100b by the second conductive via 120 passing through the dielectric layer 108, the barrier layer 106, the channel layer 104 and the buffer layer 102. The gate G is disposed on the dielectric layer 108 between the source S and the drain D.

It should be noted that in the present embodiment, the P-N junction diode 20a formed by the P-type first region I00a and the N-type second region 100b may be connected in parallel and integrated with an MIS-HEMT device 10a on the same chip, which may not only significantly reduce the use area of the chip, but also prevent the interface trapping, thereby enhancing the device performance.

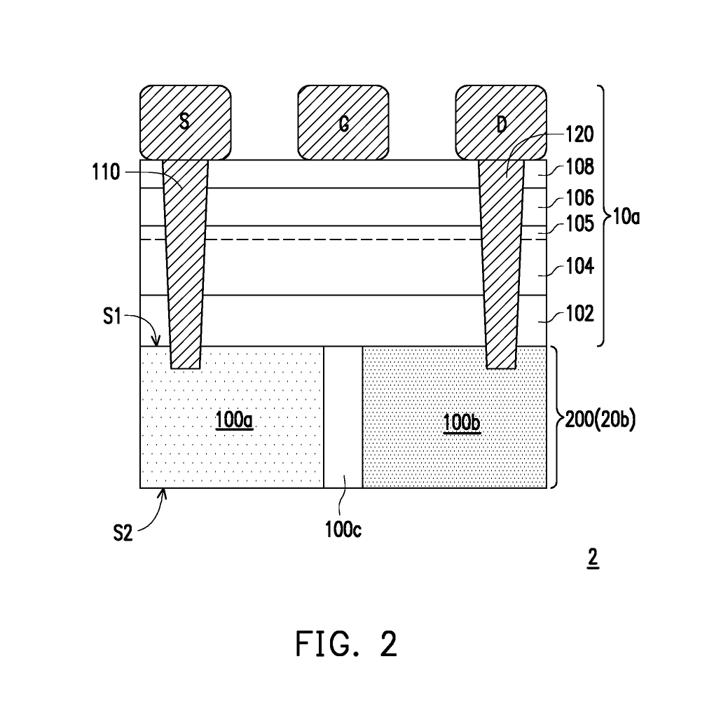

FIG. 2 is a schematic cross-sectional view showing a semiconductor device according to a second embodiment of the invention.

Referring to FIG. 2, a semiconductor device 2 of the second embodiment is basically similar to the semiconductor device 1 of the first embodiment. The difference between the two embodiments above lies in the substrate 200 of the semiconductor device 2 further including a third region 100c disposed between the first region 100a and the second region 100b. In an embodiment, the third region 100c may be an intrinsic region or a non-doped region. Thus, the P-type first region 100a, the N-type second region 100b and the intrinsic or non-doped third region 100c may form a PIN junction diode 20b. The PIN junction diode 20b is embedded in the substrate 200. In other words, the entire substrate 200 becomes the PIN junction diode 20b. In some embodiments, as shown in FIG. 2, an orthographic projection of the 2DEG 105 over the front surface (top surface) S1 of the substrate 200 is overlapped to the diode 20b.

In the present embodiment, the PIN junction diode 20b may be connected in parallel and integrated with the MIS-HEMT device 10a on the same chip, which may not only significantly reduce the use area of the chip, but also prevent the interface trapping, thereby enhancing the device performance. By being compared with the P-N junction diode, the PIN junction diode 20b is capable of withstanding a greater operating voltage (e.g., 10 V to 3000 V).

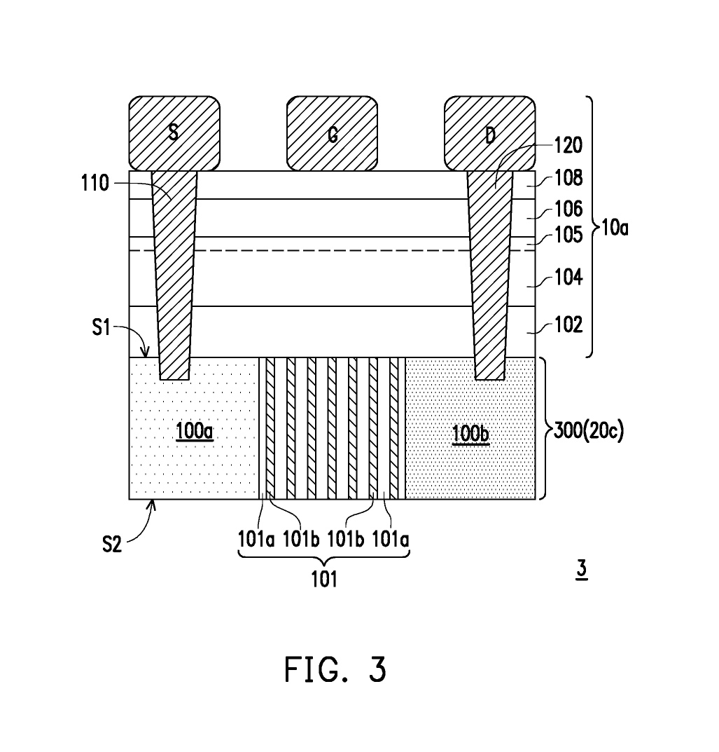

FIG. 3 is a schematic cross-sectional view showing a semiconductor device according to a third embodiment of the invention.

Referring to FIG. 3, a semiconductor device 3 of the third embodiment is basically similar to the semiconductor device 2 of the second embodiment. The difference between the two embodiments above lies in a third region 101 of the semiconductor device 3 including a multi-layer structure having a plurality of first layers 101a and a plurality of second layers 101b alternately arranged in a direction from the first region 100a towards the second region 100b. In an embodiment, the first layers 101a may be Si layers, and the second layers 101b may be SiGe layers. As shown in FIG. 3, the P-type first region 100a, the N-type second region 100b and the third region 101 having the multi-layer structure may form a resonant tunneling diode (RTD) 20c. The RTD 20c is embedded in the substrate 300. In other words, the entire substrate 300 becomes the RTD 20c. In some embodiments, as shown in FIG. 3, an orthographic projection of the 2DEG 105 over the front surface (top surface) S1 of the substrate 300 is overlapped to the diode 20c.

In the present embodiment, the RTD 20c may be connected in parallel and integrated with the MIS-HEMT device 10a on the same chip, which may not only significantly reduce the use area of the chip, but also prevent the interface trapping, thereby enhancing the device performance. The RTD 20c may contribute to increasing a bandgap width, thereby, suppressing a leakage current.

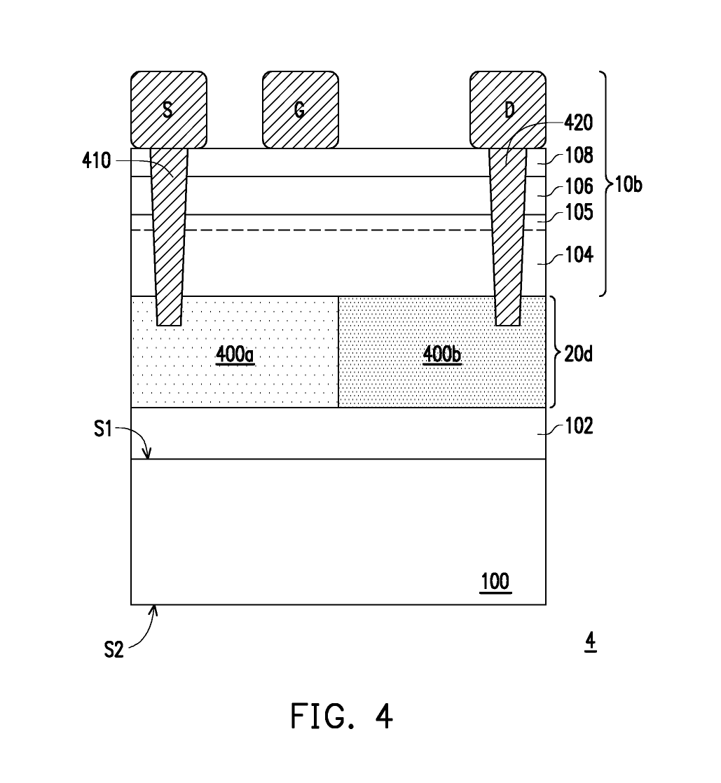

FIG. 4 is a schematic cross-sectional view showing a semiconductor device according to a fourth embodiment of the invention.

Referring to FIG. 4, a semiconductor device 4 of the fourth embodiment is basically similar to the semiconductor device 1 of the first embodiment. The difference between the two embodiments above lies in a P-N junction diode 20d of the semiconductor device 4 being disposed over the substrate 100. To be specific, the P-N junction diode 20d is disposed between the buffer layer 102 and the channel layer 104. The source S be electrically connected with a first region 400a by a first conductive via 410 passing through the dielectric layer 108, the barrier layer 106 and the channel layer 104. The drain D may be electrically connected with a second region 400b by a second conductive via 420 passing through the dielectric layer 108, the barrier layer 106 and the channel layer 104. In some embodiments, as shown in FIG. 4, an orthographic projection of the 2DEG 105 over the front surface (top surface) S1 of the substrate 100 is overlapped to an orthographic projection of the diode 20d over the front surface (top surface) S1 of the substrate 100.

In the present embodiment, the PIN junction diode 20d may be connected in parallel and integrated with the MIS-HEMT device 10b on the same chip, which may not only significantly reduce the use area of the chip, but also prevent the interface trapping, thereby enhancing the device performance.

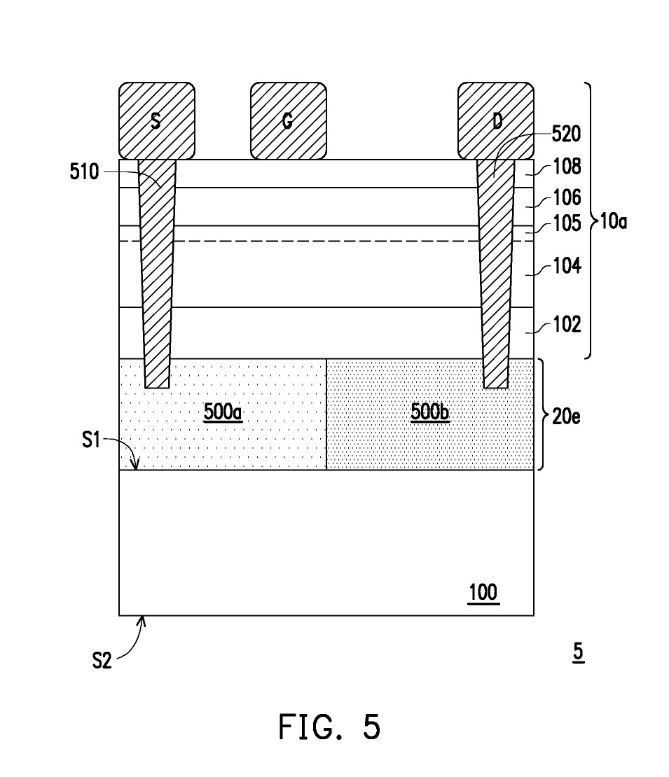

FIG. 5 is a schematic cross-sectional view showing a semiconductor device according to a fifth embodiment of the invention.

Referring to FIG. 5, a semiconductor device 5 of the fifth embodiment is basically similar to the semiconductor device 4 of the fourth embodiment. The difference between the two embodiments above lies in a P-N junction diode 20e of the semiconductor device 5 being disposed between the substrate 100 and the buffer layer 102. The source S may be electrically connected with a first region 500a by a first conductive via 510 passing through the dielectric layer 108, the barrier layer 106, the channel layer 104 and the buffer layer 102. The drain D may be electrically connected with a second region 500b by a second conductive via 520 passing through the dielectric layer 108, the barrier layer 106, the channel layer 104 and the buffer layer 102. In some embodiments, as shown in FIG. 5, an orthographic projection of the 2DEG 105 over the front surface (top surface) S1 of the substrate 100 is overlapped to an orthographic projection of the diode 20e over the front surface (top surface) S1 of the substrate 100.

In the present embodiment, the P-N junction diode 20e may be connected in parallel and integrated with the MIS-HEMT device 10a on the same chip, which may not only significantly reduce the use area of the chip, but also prevent the interface trapping, thereby enhancing the device performance.

In an embodiment, the semiconductor devices 1, 2, 3, 4 and 5 may be depletion mode (D-mode) HEM transistor devices. Namely, in a scenario that a gate voltage is not applied, the 2DEG (or a carrier channel) 105 in the channel layer 104 may be, for example, in a normally-on state, and in a scenario that the gate voltage is applied, the 2DEG (or the carrier channel) 105 in the channel layer 104 of the D-mode HEM transistor devices may be turned off.

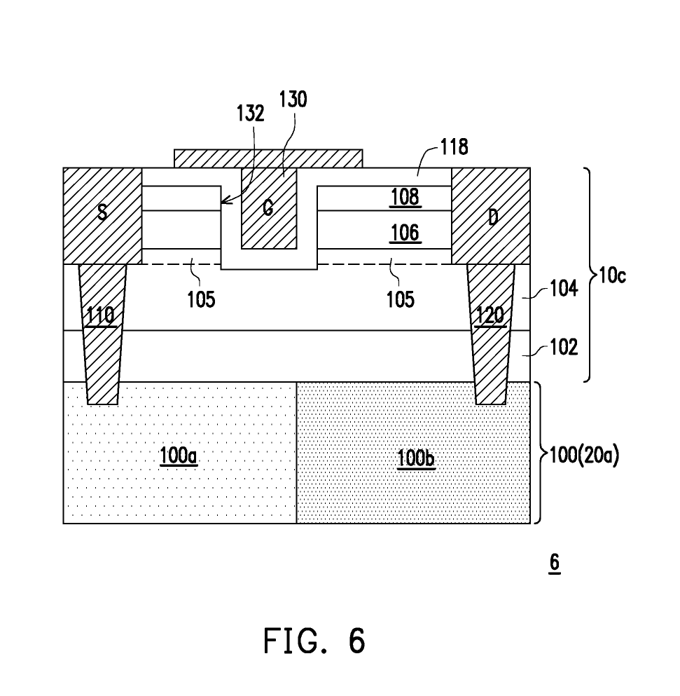

FIG. 6 is a schematic cross-sectional view showing a semiconductor device according to a sixth embodiment of the invention.

Referring to FIG. 6, a semiconductor device 6 of the sixth embodiment is basically similar to the semiconductor device 1 of the first embodiment. The difference between the two embodiments above lies in the semiconductor device 6 further including a dielectric layer 118 conformally disposed on a third opening 132 between the dielectric layer 108 and the barrier layer 106. A conductive material is filled in the third opening 132 to form a third conductive via 130. In the present embodiment, the third conductive via 130 may be considered as the gate G. The dielectric layer 118 of the third opening 132 is located between the gate G and the dielectric layer 108, between the gate G and the barrier layer 106 and between the gate G and the channel layer 104. In an embodiment, the third opening 132 at least exposes a top surface of the channel layer 104, such that the 2DEG 105 is not formed in the channel layer 104 under the third opening 132. In other embodiments, as shown in FIG. 6, the third opening 132 is further extended into the channel layer 104, such that the 2DEG 105 is disposed at two sides of the third opening 132, respectively. In other word, the 2DEG 105 is disposed in the channel layer 104 between the source S and the gate G and disposed in the channel layer 104 between the gate G and the drain D. In some embodiments, as shown in FIG. 6, an orthographic projection of the 2DEG 105 over the front surface or top surface of the substrate 100 is overlapped to the diode 20a.

In addition, the dielectric layer 118 not only conformally covers the surface of the third opening 132, but also is extended to cover a top surface of the dielectric layer 108. In an embodiment, the dielectric layer 118 may be considered as a gate dielectric layer, which is capable of reducing a leakage current of the gate G and adjusting a threshold voltage (Vth) by changing a thickness of the dielectric layer 118. A material of the dielectric layer 118 includes Al₂O₃, SiN, SiO, AlN or a combination thereof, and a method of forming the dielectric layer 118 may be an epitaxial growth method, e.g., a MOCVD method of an MBE method.

In addition, as shown in FIG. 6, the source S of the semiconductor device 6 is embedded in the dielectric layers 118, 108 and the barrier layer 106 and is electrically connected with the first region 100a by the first conductive via 110 passing through the channel layer 104 and the buffer layer 102. The drain D is also embedded in the dielectric layers 118, 108 and the barrier layer 106 and is electrically connected with the second region 100b by the second conductive via 120 passing through the channel layer 104 and the buffer layer 102. In an embodiment, the first conductive via 110 and the source S thereon may be considered as a single-source structure, and the second conductive via 120 and the drain D thereon may also be considered as a single-drain structure.

In an embodiment, the semiconductor device 6 may be an enhancement mode (E-mode) HEMT device. Namely, in a scenario that a gate voltage is not applied, the 2DEG (or the carrier channel) 105 in the channel layer 104 may be in a normally-off state, and in a scenario that the gate voltage is applied, the 2DEG (or the carrier channel) 105 in the channel layer 104 of such E-mode HEM transistor may be turned on. Additionally, in the present embodiment, the P-N junction diode 20a may be connected in parallel and integrated with an MIS-HEMT device 10c on the same chip, which may not only significantly reduce the use area of the chip, but also prevent the interface trapping, thereby enhancing the device performance.

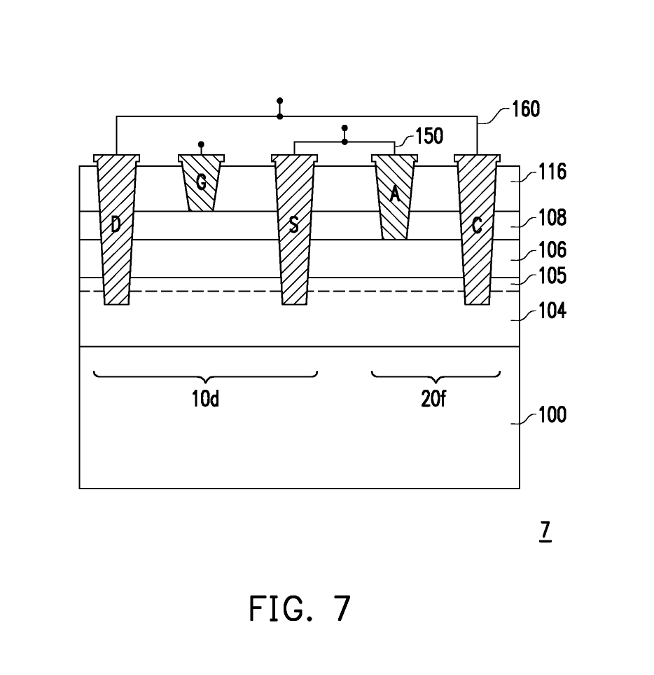

FIG. 7 is a schematic cross-sectional view showing a semiconductor device according to a seventh embodiment of the invention.

The present embodiment provides a semiconductor device 7 including the substrate 100, the channel layer 104, the barrier layer 106, the dielectric layer 108, an interlayer dielectric layer 116, the source S, the drain D, the gate G, an anode A and a cathode C. The channel layer 104 (which has the 2DEG 105 in the region adjacent to the barrier layer 106), the barrier layer 106, the dielectric layer 108 and the interlayer dielectric layer 116 are sequentially disposed on the substrate 100.

In an embodiment, the source S may be a conductive via type passing through the interlayer dielectric layer 116, the dielectric layer 108 and the barrier layer 106 and be electrically connected with the channel layer 104. In an alternative embodiment, as shown in FIG. 7, the source S may also be extended into the channel layer 104, such that the 2DEG 105 is located at two sides of the source S.

In an embodiment, the drain D may be a conductive via type passing through the interlayer dielectric layer 116, the dielectric layer 108 and the second conductive via 120 of the barrier layer 106 and be electrically connected with the channel layer 104. In an alternative embodiment, as shown in FIG. 7, the drain D may also be extended into the channel layer 104, such that the 2DEG 105 is located at two sides of the drain D.

In an embodiment, the gate G may be a conductive via type passing through the interlayer dielectric layer 116 and disposed on the dielectric layer 108 between the source S and the drain D. In an embodiment, the anode A may be a conductive via type passing through the interlayer dielectric layer 116 and the dielectric layer 108, electrically connected with the barrier layer 106 and electrically connected with the source S by the first interconnect 150. In an embodiment, the cathode C may be a conductive via type passing through the interlayer dielectric layer 116, the dielectric layer 108 and the barrier layer 106, electrically connected with the channel layer 104 and electrically connected with the drain D by the second interconnect 160. In an alternative embodiment, as shown in FIG. 7, the cathode C may also be extended into the channel layer 104, such that the 2DEG 105 is located at two sides of the cathode C.

In an embodiment, the anode A and the barrier layer 106 may form a Schottky diode 20f. The cathode C and the channel layer 104 may form an ohmic contact. Thus, the MIS-HEMT device 10d may be connected in parallel and integrated with the Schottky diode 20f on the same chip by the first interconnect 150 and the second interconnect 160. Namely, in the invention, different devices (which are not limited to the MIS-HEMT device) may be connected in parallel and integrated with various diodes on the same chip by means of interconnects, so as to reduce the use area of the chip.

In some embodiments, the 2DEG 105 is disposed in the channel layer 104 between the source S and the drain D and disposed in the channel layer 104 between the source S and the cathode C. In some alternative embodiments, as shown in FIG. 7, an orthographic projection of the 2DEG 105 over the front surface or top surface of the substrate 100 is overlapped to an orthographic projection of the Schottky diode 20f over the front surface or top surface of the substrate 100.

In other embodiments, the semiconductor device 7 may also include a buffer layer (which is not shown) disposed between the substrate 100 and the channel layer 104 to reduce a difference of lattice constant and a difference of CTE between the substrate 100 and the channel layer 104.

In light of the foregoing, in the invention, the MIS-HEMT device and the diode can be connected in parallel and integrated with each other on the same chip by the single-chip integration technique, which can not only significantly reduce the use area of the chip, but also prevent the interface trapping, thereby enhancing the device performance.

Although the invention has been described with reference to the above embodiments, it will be apparent to one of the ordinary skill in the art that modifications to the described embodiment may be made without departing from the spirit of the invention. Accordingly, the scope of the invention will be defined by the attached claims not by the above detailed descriptions.

What is claimed is:

1. A semiconductor device, comprising:
a diode, disposed over a substrate or in the substrate, wherein the diode comprises a first region with a first conductive type and a second region with a second conductive type, and the first conductive type is different from the second conductive type;
a channel layer, disposed over the diode;
a barrier layer, disposed over the channel layer;
a first dielectric layer, disposed over the barrier layer;
a source, electrically connected to the first region of the diode by a first conductive via through the first dielectric layer, the barrier layer, and the channel layer;
a drain, electrically connected to the second region of the diode by a second conductive via through the first dielectric layer, the barrier layer, and the channel layer;
a gate, disposed over the channel layer between the source and the drain; and
a two-dimensional electron gas (2DEG), disposed in the channel layer between the source and the drain.

2. The semiconductor device according to claim 1, wherein the first region of the diode is connected with the second region of the diode.

3. The semiconductor device according to claim 1, wherein a third region is between the first region of the diode and the second region of the diode, and the third region is an intrinsic region or a non-doped region.

4. The semiconductor device according to claim 1, wherein a third region is between the first region of the diode and the second region of the diode, the third region comprises a multi-layer structure having a plurality of first layers and a plurality of second layers which are alternately arranged along a direction from the first region to second region.

5. The semiconductor device according to claim 1, further comprising a buffer layer, located between the channel layer and the substrate.

6. The semiconductor device according to claim 5, wherein the diode is located between the channel layer and the buffer layer, or the diode is located between the buffer layer and the substrate.

7. The semiconductor device according to claim 1, wherein the semiconductor device is an enhancement mode high electron mobility transistor (HEMT) device, and the enhancement mode HEMT device further comprises:
a second dielectric layer, conformally disposed in an opening formed by the first dielectric layer and the barrier layer, and the gate being filled in the opening, such that the second dielectric layer in the opening is located between the gate and the first dielectric layer, between the gate and the barrier layer and between the gate and the channel layer.

8. The semiconductor device according to claim 1, wherein an orthographic projection of the two-dimensional electron gas (2DEG) over a top surface of the substrate is overlapped to an orthographic projection of the diode over the top surface of the substrate.

9. A semiconductor device, comprising:
a channel layer, disposed over a substrate;
a barrier layer, disposed over the channel layer;
a dielectric layer, disposed over the barrier layer;
a source, passing through the dielectric layer and the barrier layer and electrically connected with the channel layer;
a drain, passing through the dielectric layer and the barrier layer and electrically connected with the channel layer;
a gate, disposed over the dielectric layer between the source and the drain;
an anode, passing through the dielectric layer, electrically connected with the barrier layer and electrically connected with the source by a first interconnect, wherein the anode and the barrier layer form a Schottky diode;
a cathode, passing through the dielectric layer and the barrier layer, electrically connected with the channel layer and electrically connected with the drain by a second interconnect; and
a two-dimensional electron gas (2DEG), disposed in the channel layer between the source and the drain and disposed in the channel layer between the source and the cathode.

10. The semiconductor device according to claim 9, wherein an orthographic projection of the two-dimensional electron gas (2DEG) over a top surface of the substrate is overlapped to an orthographic projection of the Schottky diode over the top surface of the substrate.

11. The semiconductor device according to claim 9, wherein the cathode and the channel layer form an ohmic contact.

12. A method of manufacturing a semiconductor device, comprising:
sequentially forming a channel layer, a barrier layer and a dielectric layer over a front surface of a substrate;
respectively forming a first region with a first conductive type and a second region with a second conductive type in the substrate, wherein the first conductive type is different from the second conductive type;
forming a first conductive via in the dielectric layer, the barrier layer and the channel layer, such that a source is electrically connected with the first region by the first conductive via;
forming a second conductive via in the dielectric layer, the barrier layer and the channel layer, such that a drain is electrically connected with the second region by the second conductive via;
forming a gate on the dielectric layer between the source and the drain; and
forming a two-dimensional electron gas (2DEG) in the channel layer between the source and the drain.

13. The method of manufacturing the semiconductor device according to claim 12, wherein the step of respectively forming the first region and the second region in the substrate comprises:
after forming the dielectric layer over the front surface of the substrate, forming a first mask pattern over a back surface of the substrate to cover the second region and expose the first region;
performing a first ion implantation process on the first region;
removing the first mask pattern;
forming a second mask pattern over the back surface of the substrate to cover the first region and expose the second region; and
performing a second ion implantation process on the second region.

14. The method of manufacturing the semiconductor device according to claim 12, where the first region is connected with the second region.

15. The method of manufacturing the semiconductor device according to claim 12, wherein a third region is between the first region and the second region, and the third region is an intrinsic region, a non-doped region or a multi-layer structure.

16. The method of manufacturing the semiconductor device according to claim 12, wherein a method of forming the first conductive via and the second conductive via comprises:
forming a third mask pattern over the dielectric layer to define positions of the first conductive via and the second conductive via;
removing a part of the dielectric layer, a part of the barrier layer and a part of the channel layer to form a first opening and a second opening by using the third mask pattern as a mask, wherein a part of a surface of the first region of the substrate is exposed by the first opening, and a part of a surface of the second region of the substrate is exposed by the second opening; and
filling a conductive material in the first opening and the second opening.

17. The method of manufacturing the semiconductor device according to claim 12, further comprising: performing an annealing process after forming the first conductive via and the second conductive via.

18. The method of manufacturing the semiconductor device according to claim 12, wherein an orthographic projection of the two-dimensional electron gas (2DEG) over a top surface of the substrate is overlapped to an orthographic projection of the first region and the second region over the top surface of the substrate.
